(19) United States
(12) Patent Application Publication
(10) Pub. No.: US 2025/0056869 A1
(43) Pub. Date: Feb. 13, 2025

(54) WIDE BAND GAP SEMICONDUCTOR DEVICE

(71) Applicant: Infineon Technologies AG, Neubiberg (DE)

(72) Inventors: Fabian RASINGER, Villach (AT); Michael HELL, Erlangen (DE); Thomas AICHINGER, Faak am See (AT); Alexey MIKHAYLOV, Villach (AT)

(21) Appl. No.: 18/799,436

(22) Filed: Aug. 9, 2024

(30) Foreign Application Priority Data
Aug. 10, 2023 (DE) 102023121453.5

(51) Int. Cl. H01L 29/51; H01L 23/528; H01L 23/532; H01L 27/088; H01L 29/423

(52) U.S. Cl. CPC H01L 29/512; H01L 23/5286; H01L 23/5329; H01L 27/088; H01L 29/4236

(57) ABSTRACT

A wide band gap semiconductor device is proposed. The wide band gap semiconductor device includes a wide band gap semiconductor body having a first surface and a second surface opposite to the first surface along a vertical direction. A gate electrode structure is arranged in an active transistor area. The gate electrode structure includes a gate electrode and a gate dielectric arranged between the gate electrode and the wide band gap semiconductor body. A gate interconnection structure is arranged outside of the active transistor area. The gate interconnection structure includes an interconnection electrode and an interconnection dielectric arranged between the interconnection electrode and the wide band gap semiconductor body. Dielectric constants of a main dielectric component of at least two of i) a part of the gate interconnection dielectric, or ii) a first part of the gate dielectric, or iii) a second part of the gate dielectric differ from one another.

### RELATED APPLICATION

This application claims priority to German Patent Application No. 102023121453.5, filed on Aug. 10, 2023, entitled “WIDE BAND GAP SEMICONDUCTOR DEVICE”, which is incorporated by reference herein in its entirety.

### TECHNICAL FIELD

The present disclosure is related to a wide band gap semiconductor device, in particular to a wide band gap semiconductor device including a gate electrode structure and a gate interconnection structure.

### BACKGROUND

Technology development of new generations of wide band gap semiconductor devices, e.g. insulated gate field effect transistors (IGFETs) such as metal oxide semiconductor field effect transistors (MOSFETs) or insulated gate bipolar transistors (IGBTs), aims at improving electric device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RonXA, may have an impact on other electric device characteristics such as, for example, gate-to-drain capacitance, CGD.

There is a need for improving electric characteristics of wide band gap semiconductor devices.

### SUMMARY

An example of the present disclosure relates to a wide band gap semiconductor device including a wide band gap semiconductor body having a first surface and a second surface opposite to the first surface along a vertical direction. The wide band gap semiconductor device further includes a gate electrode structure arranged in an active transistor area. The gate electrode structure includes a gate electrode and a gate dielectric arranged between the gate electrode and the wide band gap semiconductor body. The wide band gap semiconductor device further includes a gate interconnection structure arranged outside of the active transistor area. The gate interconnection structure includes an interconnection electrode and an interconnection dielectric arranged between the interconnection electrode and the wide band gap semiconductor body. A dielectric constants of a main dielectric component of at least two of i) a part of the interconnection dielectric, or ii) a first part of the gate dielectric, or iii) a second part of the gate dielectric differ from one another.

Another example of the present disclosure relates to a method of manufacturing a wide band gap semiconductor device. The method incudes providing a wide band gap semiconductor body having a first surface and a second surface opposite to the first surface along a vertical direction. The method further includes forming a gate electrode structure in an active transistor area. The gate electrode structure includes a gate electrode and a gate dielectric arranged between the gate electrode and the wide band gap semiconductor body. The method further includes forming a gate interconnection structure outside of the active transistor area. The gate interconnection structure includes an interconnection electrode and an interconnection dielectric arranged between the interconnection electrode and the wide band gap semiconductor body. Dielectric constants of a main dielectric component of at least two of i) a part of the interconnection dielectric, or ii) a first part of the gate dielectric, or iii) a second part of the gate dielectric differ from one another.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of wide band gap semiconductor devices and together with the description serve to explain principles of the embodiments. Further embodiments are described in the following detailed description and the claims.

FIG. 1A schematically and exemplarily shows a partial cross-sectional view of a configuration example of a wide band gap semiconductor device.

FIG. 1B schematically and exemplarily shows a top view of a configuration example of a wide band gap semiconductor device.

FIGS. 1C and 1D are exemplary cross-sectional views along intersection lines AA′ and BB′ of FIG. 1B.

FIG. 2 schematically and exemplarily shows a partial cross-sectional view of another configuration example of a wide band gap semiconductor device.

FIGS. 3A to 3C schematically and exemplarily show a top view and perspective views of another configuration example of a wide band gap semiconductor device.

FIG. 4 schematically and exemplarily shows a partial cross-sectional view of a configuration example of a wide band gap semiconductor device including a trench gate interconnection structure.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

An example a wide band gap semiconductor device includes a wide band gap semiconductor body having a first surface and a second surface opposite to the first surface along a vertical direction. The wide band gap semiconductor device includes a gate electrode structure arranged in an active transistor area. The gate electrode structure includes a gate electrode and a gate dielectric arranged between the gate electrode and the wide band gap semiconductor body. The gate interconnection structure may be arranged outside of the active transistor area. The gate interconnection structure includes an interconnection electrode and an interconnection dielectric arranged between the interconnection electrode and the wide band gap semiconductor body. Dielectric constants of a main dielectric component of at least two of i) a part of the gate interconnection dielectric, or ii) a first part of the gate dielectric, or iii) a second part of the gate dielectric may differ from one another.

The wide band gap semiconductor device may be part of an integrated circuit or may be a discrete semiconductor device or a semiconductor module, for example. The wide band gap semiconductor device may be or may include an insulated gate field effect transistor (IGFET) such as a metal oxide semiconductor field effect transistor (MOSFET) or an insulated gate bipolar transistor (IGBT), for example. The wide band gap semiconductor device may be a vertical semiconductor device having a load current flow between the first surface and the second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The wide band gap semiconductor device may be based on a semiconductor body from a crystalline wide band gap semiconductor material having a band gap larger than the band gap of silicon, i.e. larger than 1.12 eV. The wide band gap semiconductor material may have a hexagonal crystal lattice and may be silicon carbide (SiC) or gallium nitride (GaN), by way of example. For example, the semiconductor material may be 2H-SiC (SiC of the 2H polytype), 6H-SIC or 15R-SiC. According to an example, the semiconductor material is silicon carbide of the 4H polytype (4H-SiC). The semiconductor body may include or consist of a semiconductor substrate having none, one or more than one semiconductor layers, e.g. epitaxially grown layers, thereon.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

For example, the gate electrode structure may be stripe-shaped and a second lateral direction may be a longitudinal direction of the stripe-shaped gate electrode structure, for example. The gate electrode structure may also have another layout or geometry in a plan view, e.g. hexagonal, square, circular, elliptic. The gate electrode structure may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. The gate electrode structure may be electrically connected to a gate pad via the gate interconnection structure, for example. The gate pad and, for example, a first load electrode pad, e.g. a source pad of a MOSFET or an emitter pad of an IGBT, may be part of a wiring area over the wide band gap semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) and/or contact line(s) may be formed in openings of the interlayer dielectric structure to electrically connect parts, e.g. metal lines or contact areas, of different wiring levels to one another.

For realizing a desired current carrying capacity, the wide band gap semiconductor device may be designed by a plurality of parallel-connected wide band gap semiconductor device cells. The parallel-connected wide band gap semiconductor device cells may, for example, be wide band gap semiconductor device cells formed in the shape of a strip or a strip segment. Of course, the wide band gap semiconductor device cells can also have any other shape, e.g. circular, elliptical, polygonal such as hexagonal or octahedral. The wide band gap semiconductor device cells may be arranged in the active transistor area of the semiconductor body. The active transistor area may be an area where an emitter region of an IGBT (or a source region of a MOSFET) and a collector region of an IGBT (or a drain region of a MOSFET) are arranged opposite to one another along the vertical direction. In the active transistor area, a load current may enter or exit the semiconductor body of the wide band gap semiconductor device, e.g. via contact plugs on the first surface of the wide band gap semiconductor body. The wide band gap semiconductor device may further include an edge termination area that may include a termination structure. In a blocking mode or in a reverse biased mode of the wide band gap semiconductor device, the blocking voltage between the active transistor area and a field-free region laterally drops across the termination structure. The termination structure may have a higher or a slightly lower voltage blocking capability than the active area. The termination structure may include a junction termination extension (JTE) with or without a variation of lateral doping (VLD), one or more laterally separated guard rings, or any combination thereof, for example.

The gate interconnection structure outside of the active transistor cell area may be arranged laterally between the active transistor cell area and the edge termination area. The interconnection electrode may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. At least part of the interconnection electrode may be a so-called gate runner that merges with the gate pad.

The main dielectric component of a dielectric structure or part of a dielectric structure is the dielectric material that has a largest volume fraction with respect to the dielectric structure or the part of the dielectric structure. For example, for a dielectric structure having three stacked layers with thicknesses d1, d2, d3 and corresponding dielectric materials m1, m2, m3, wherein d1<d2<d3, the main dielectric component of the dielectric structure is given by the dielectric material m3.

When dielectric constants of a main dielectric component at least two of i) a part of the gate interconnection dielectric, or ii) a first part of the gate dielectric, or iii) a second part of the gate dielectric differ from one another, combinations as follows may occur:
the dielectric constant of the main dielectric component of a part of the interconnection dielectric differs from, e.g. is smaller or larger than, the dielectric constant of a first part of the gate dielectric—for this case the dielectric constant of the main dielectric component of a second part of the gate dielectric may have any value, e.g. be equal to the dielectric constant of the main dielectric component of the first part or be equal to the dielectric constant of the main dielectric component of the interconnection dielectric;
the dielectric constant of the main dielectric component of a part of the interconnection dielectric differs from, e.g. is smaller or larger than, the dielectric constant of the main dielectric component of a second part of the gate dielectric—for this case the dielectric constant of the main dielectric component of a first part of the gate dielectric may have any value, e.g. be equal to the dielectric constant of the main dielectric component of the second part or be equal to the dielectric constant of the main dielectric component of the interconnection dielectric;
the dielectric constant of the main dielectric component of a first part of the gate dielectric differs from, e.g. is smaller or larger than, the dielectric constant of the main dielectric component of a second part of the gate dielectric—for this case the dielectric constant of the main dielectric component of a part of the interconnection dielectric may have any value, e.g. be equal to the dielectric constant of the main dielectric component of the first part of the gate dielectric or be equal to the dielectric constant of the main dielectric component of the second part of the gate dielectric;
the dielectric constant of the main dielectric component of a part of the interconnection dielectric differs from, e.g. is smaller or larger than, the dielectric constant of the main dielectric component of a first part of the gate dielectric and further differs from, e.g. is smaller or larger than, the dielectric constant of the main dielectric component of a second part of the gate dielectric, and the dielectric constant of the main dielectric component of the first part of the gate dielectric differs from, e.g. is smaller or larger than, the dielectric constant of the main dielectric component of the second part of the gate dielectric.

When using different dielectric constants in the main dielectric component of different parts of the dielectric structure of the gate electrode structure/gate interconnection structure, the gate-to-source capacitance, CGS, may be increased, e.g. for reducing parasitic turn-on, without adversely affecting the trade-off between Rds and CGD. Moreover, a contribution to the gate-to-source capacitance, CGS, originating from outside the active transistor area, e.g. a gate interconnection area, may also be tuned, e.g. via ALD deposition and patterning of a high-k dielectric layer. This allow for reducing electric losses of the gate driver circuitry, for example.

For example, the gate electrode structure may be a trench gate electrode structure. The first part of the gate dielectric may adjoin to a channel region. The second part of the gate dielectric may adjoin to a non-channel region. For example, sidewalls of the trench gate electrode structure may be non-tapered or slightly tapered, for example. In case of slightly tapered sidewalls of the trench gate electrode structure, a channel length may be slightly larger than the vertical extent of a channel region. The taper angle of the trench gate structure may be caused by process technology, e.g. aspect ratio of trench etch processes, and may also be used for maximizing the charge carrier mobility in the channel region which depends from the direction along which channel current flows. Another example for a tapered trench gate structure is a V-shaped trench gate structure. The channel region may be defined a part of a body region that adjoins to the gate dielectric structure at a sidewall of the trench gate electrode structure. For example, a conductivity of the channel region may be controlled by a potential applied to the gate electrode structure, e.g. by field effect. For example, a positive voltage applied to the trench gate electrode structure in an n-channel MOSFET may induce an n-inversion channel in part of a p-doped body region adjoining gate dielectric, for example. The body region may be electrically connected via the first surface, e.g. by a contact plug on a top surface of the body region and/or a groove contact that may extend into the wide band gap semiconductor body and may be electrically connected to the body region via a sidewall of the groove contact. The channel region part of the body region may include a partial compensation by dopants of the second conductivity type, e.g. n-type dopants in case of a p-doped body region, for adjusting the threshold voltage, for example. The partial compensation may be achieved by a tilted ion implantation through a sidewall of a trench, for example.

For example, a main dielectric component of the first part of the gate dielectric may be an oxide of silicon. The main dielectric component of the second part of the gate dielectric may be a high-k dielectric material.

For example, the first part of the gate dielectric may include the high-k dielectric material, or the second part of the gate dielectric may include the oxide of silicon. The high-k material of the first part of the gate dielectric may be a material remainder caused by process technology, for example. For example, a thickness of a layer of the main dielectric component of the first part of the gate dielectric, e.g. SiO₂, may be larger, e.g. larger by a factor of 2 or more, or larger by a factor of 5 or more (e.g. 10 to 100 times larger) than a thickness of a layer of the high-k dielectric material of the first part of the gate dielectric. For example, the thickness of the remainder layer of high-k material may be in a range from 1 nm to 10 nm. Likewise, the oxide of silicon of the second part of the gate dielectric may be a material remainder caused by process technology, for example. For example, a thickness of a layer of the main dielectric component of the second part of the gate dielectric, e.g. high-k dielectric material, may be larger, e.g. larger by a factor of 2 or more, or larger by a factor of 5 or more (e.g. 10 to 100 times larger) than a thickness of a layer of the oxide of silicon of the second part of the gate dielectric.

For example, a main dielectric component of the first part of the gate dielectric may be a high-k dielectric material. The main dielectric component of the second part of the gate dielectric may be an oxide of silicon. This may allow for reducing losses caused by channel conductivity. This may further allow for limiting the gate charge in case of uncritical CGD/CGS.

For example, the first part of the gate dielectric may be arranged at a first sidewall of the trench gate electrode structure. The second part of the gate dielectric may be arranged at a second sidewall of the trench gate electrode structure. The second sidewall is opposite to the first sidewall along a first lateral direction.

For example, the first part of the gate dielectric may adjoin to a p-doped body region including the channel region. The first part of the gate dielectric may further adjoin to an n⁺-source region arranged between the p-doped body region and the first surface of the wide band gap semiconductor body. The first part of the gate dielectric may further adjoin to an n-doped current spread region arranged below the p-doped region, e.g. arranged between the p-doped region and the second surface of the wide band gap semiconductor body. The n-doped current spread region may have a larger n-type doping concentration than an n-doped drift region arranged below the current spread region. The n-doped drift region may be arranged between the n-doped current spread region and the second surface. The second part of the gate dielectric may adjoin to a p-doped diode region being at least part of the non-channel region. A bottom side of the p-doped diode region may have a large vertical distance to the first surface than a bottom side of the trench gate electrode structure, for example. The p-doped diode region may include a plurality of p-doped sub-regions, e.g. two, three, four, five, or more, having vertically overlapping p-type doping concentration profiles, for example.

For example, the p-doped diode region may adjoin to a first part of a bottom side of the trench gate structure.

For example, the first part of the gate dielectric may merge into the second part of the gate dielectric at a bottom side of the trench gate structure.

For example, the p-doped diode region may adjoin to the first part of the gate dielectric and to the second part of the gate dielectric at the bottom side of the trench gate structure.

For example, the wide band gap semiconductor device may further include a third part of the gate dielectric. The third part of the gate dielectric and the second part of the gate dielectric may have a same material composition, e.g. may include a high-k dielectric material as the main dielectric component. The third part of the gate dielectric may be arranged at the first sidewall of the trench gate electrode structure.

For example, the third part of the gate dielectric may merge into the first part of the gate dielectric along a second lateral direction. The second lateral direction may be a longitudinal direction of the trench gate electrode structure. In other words, the channel region may be formed by channel sub-regions that are laterally spaced from one another along the longitudinal direction of the trench gate structure, for example. Between neighboring channel sub-regions, a non-channel region, e.g. the diode region, adjoining to the third part of the gate dielectric may be arranged, for example.

For example, the gate interconnection structure may include a trench gate interconnection structure. The trench gate interconnection structure may merge into the gate electrode structure. For example, longitudinal directions of the trench gate interconnection structure and the gate electrode structure may differ from one another, e.g. be perpendicular to one another, in some areas of the wide band gap semiconductor device.

For example, the trench gate interconnection structure, in a cross-sectional view, may only adjoin to non-channel parts of the wide band gap semiconductor body. In other words, the trench gate interconnection structure may not act as a transistor cell by controlling a conductivity in a channel region via field effect. For example, the trench interconnection structure may include parts or segments that are surrounded by the diode regions. In other words, the diode region may not only adjoin to one sidewall, but also to a bottom side and an opposite sidewall as well.

For example, a main dielectric component of the first part of the gate dielectric may be an oxide of silicon, and the main dielectric component of the part of the interconnection dielectric may be a high-k dielectric material. This may allow for a further increase of CGS without adversely affecting the trade-off between RonXA and CGD.

For example, the high-k dielectric material may include at least one of Al₂O₃, ZrO₂, HfO₂, AlN, alumisilicate AlSiOₓ, silicon doped HfO₂, lanthanum doped HfO₂, TiO₂, Y₂O₃ or Si₃N₄, ONO (oxide-nitride-oxide), or any stacked combination thereof.

For example, a main dielectric component of the first part of the gate dielectric may be an oxide of silicon. The main dielectric component of the part of the interconnection dielectric may be a low-k dielectric material. This may allow for improving the resonant switching behavior of the wide band gap semiconductor device, for example. The low-k dielectric material may include at least one of SiO₂, phosphorus or carbon doped SiO₂, or porous SiO₂.

For example, the gate electrode structure may be a planar gate electrode structure.

Details with respect to structure, or function, or technical benefit of features described above with respect to a wide band gap semiconductor device such as a FET, or IGBT likewise apply to the exemplary methods described herein. Processing the semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts,-functions,-processes,-operations or -steps, respectively. Such sub acts may be included and part of the disclosure of this single act unless explicitly excluded.

An example of the present disclosure relates to a method of manufacturing a wide band gap semiconductor device. The method includes providing a wide band gap semiconductor body having a first surface and a second surface opposite to the first surface along a vertical direction. The method further includes forming a gate electrode structure in an active transistor area. The gate electrode structure includes a gate electrode and a gate dielectric arranged between the gate electrode and the wide band gap semiconductor body. The method further includes forming a gate interconnection structure outside of the active transistor area. The gate interconnection structure includes an interconnection electrode and an interconnection dielectric arranged between the interconnection electrode and the wide band gap semiconductor body. Dielectric constants of a main dielectric component of at least two of i) a part of the interconnection dielectric, or ii) a first part of the gate dielectric, or iii) a second part of the gate dielectric may differ from one another.

The examples and features described above and below may be combined.

Some of the above and below examples are described in connection with a silicon carbide substrate. Alternatively, a wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a silicon carbide (SiC) wafer, or gallium arsenide (GaAs) wafer, or a gallium nitride (GaN) wafer.

More details and aspects are mentioned in connection with the examples described above or below. Processing a wide band gap semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

In the following, further examples of field effect transistors, FETs, are explained in connection with the accompanying drawings. Functional and structural details described with respect to the examples above shall likewise apply to the exemplary embodiments illustrated in the figures and described further below. In the illustrated examples, n-channel FETs are illustrated. However, the examples described herein may also be applied to p-channel devices, e.g. p-channel MOSFETs or p-channel devices IGBTs.

Details with respect to structure, or function, or technical benefit of features described above likewise apply to the examples below and vice versa.

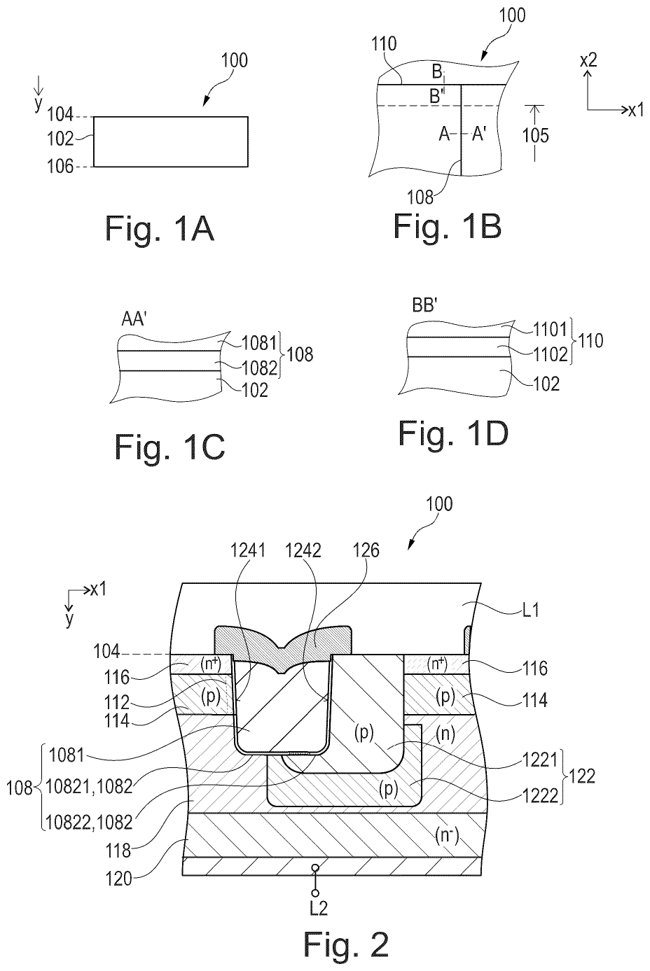

FIG. 1A schematically and exemplarily shows a partial cross-sectional view of a configuration example of a wide band gap semiconductor device 100, and FIG. 1B illustrates an exemplary top view on the wide band gap semiconductor device illustrated in FIG. 1A.

Referring to FIGS. 1A, 1B, the wide band gap semiconductor device 100 includes a wide band gap semiconductor body 102, e.g. a SiC semiconductor body. The wide band gap semiconductor body 102 has a first surface 104 and a second surface 106 opposite to the first surface 104 along a vertical direction y. A stripe-shaped gate electrode structure 108 extends along a second lateral direction x2 and is arranged in an active transistor area 105. A stripe-shaped gate interconnection structure 110 is arranged outside of the active transistor area 105, and extends along a first lateral direction x1. The gate electrode structure 108 merges with the gate interconnection structure 110. The gate interconnection structure 110 may electrically couple a gate electrode of the gate electrode structure 108 to a gate pad (not illustrated in FIGS. 1A, 1B).

FIGS. 1C, 1D schematically and exemplarily show partial cross-sectional views along intersection lines AA′, BB′ illustrated of the wide band gap semiconductor device of FIG. 1B.

Referring to FIG. 1C, the gate electrode structure 108 includes a gate electrode 1081 and a gate dielectric 1082 arranged between the gate electrode 1081 and the wide band gap semiconductor body 102. Referring to FIG. 1D, the gate interconnection structure 110 includes an interconnection electrode 1101 and an interconnection dielectric 1102 arranged between the interconnection electrode 1101 and the wide band gap semiconductor body 102. Dielectric constants of a main dielectric component of the gate interconnection dielectric 1102 and the gate dielectric differ from one another.

FIG. 2 schematically and exemplarily shows a partial cross-sectional view of a configuration example of a wide band gap semiconductor device 100 in the active transistor area 105. The wide band gap semiconductor device 100 may be a vertical power semiconductor device that further includes an edge termination area that at least partially surrounds the active transistor area 105 and the gate interconnection structure 110 (not illustrated in FIG. 1A).

The gate electrode structure 108 is a trench gate electrode structure and includes a gate electrode 1081 and a gate dielectric 1082 arranged between the gate electrode 1081 and the wide band gap semiconductor body 102. A first part 10821 of the gate dielectric 1082 adjoins to a channel region 112. The channel region 112 is defined by a part of a p-doped body region 114 that adjoins to the gate dielectric 1081 at a first sidewall 1241 of the gate electrode structure 108. For example, a conductivity of the channel region 112 may be controlled by a potential applied to the gate electrode 1082, e.g. by field effect. For example, a positive voltage applied to the gate electrode 1081 may induce an n-type inversion channel in the channel region 112 adjoining to the gate dielectric 1082, for example. The p-doped body region 114 may be electrically connected to a first load electrode L1 via the first surface 104, e.g. by a contact plug on a top surface of the body region 114 and/or a groove contact that may extend into the wide band gap semiconductor body 102 and may be electrically connected to the body region 114 via a sidewall of the groove contact (not illustrated in FIG. 2). The channel region 112 as part of the body region 114 may include a partial compensation by n-type dopants for adjusting the threshold voltage, for example. The partial compensation may be achieved by a tilted ion implantation through a sidewall of a trench, for example. The first part 10821 of the gate dielectric 1082 also adjoins to an n⁺-doped source 116 region that is arranged between the p-doped body region 114 and the first surface 104. The first part 10821 of the gate dielectric 1082 further adjoins to an n-doped current spread region 118 that is arranged between the p-doped body region 114 and an n-doped drift region 120. The n-doped drift region 120 has a smaller doping concentration than the current spread region 118. The n-doped drift region is electrically coupled to a second load electrode L2 via the second surface 106 of the wide band gap semiconductor body 102.

The second part 10822 of the gate dielectric 1081 adjoins to a p-doped diode region 122. The p-doped diode region 122 is a non-channel region similar to the source region 116 and the current spread region 118. A main dielectric component of the first part 10821 of the gate dielectric 1082 may be an oxide of silicon, and the main dielectric component of the second part 10822 of the gate dielectric 1082 may be a high-k dielectric material, for example. Depending on process technology, the first part 10821 of the gate dielectric 1082 may include a high-k dielectric material (as process remainder, for example), and/or the second part 10822 of the gate dielectric 1082 may include the oxide of silicon (as process remainder, for example).

The first part 10821 of the gate dielectric 1082 is arranged at a first sidewall 1241 of the trench gate electrode structure 108. The second part 10822 of the gate dielectric 1082 is arranged at a second sidewall 1242 of the trench gate electrode structure 108. The second sidewall 1242 is opposite to the first sidewall 1241 along the first lateral direction x1.

The p-doped diode region 122 includes a first sub-region 1221 and a second sub-region 1222. Doping concentration profiles of the first and second sub-regions 1221, 1222 overlap one another along the vertical direction y. The number of sub-regions may also differ from the illustrated example of two sub-regions, e.g. be three, or four, or five, or even more. The p-doped diode region 122 also adjoins to the first and second parts 10821, 10822 of the gate dielectric 1082 at a bottom side of the trench gate structure 108. The first part 10821 of the gate dielectric 1082 merges into the second part 10822 of the gate dielectric 1082 at the bottom side of the trench gate structure 108. The gate electrode 1081 of the trench gate structure 108 may be electrically isolated from the first load electrode L1 by an intermediate dielectric 126. In some examples, the p-doped diode region 122 is a single region and, thus, not defined by multiple sub-regions.

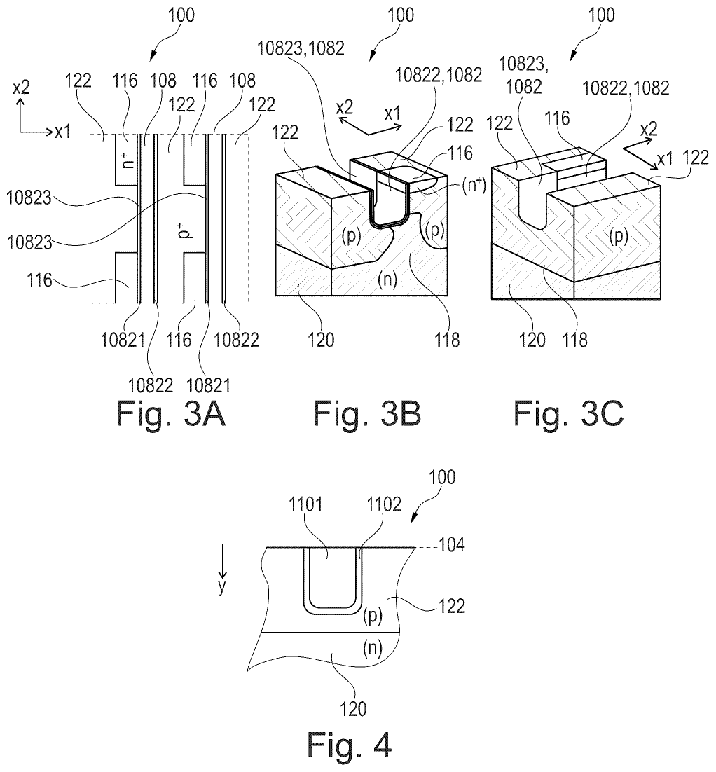

FIG. 3A schematically and exemplarily shows a top view on a wide band gap semiconductor device 100 according to another configuration example. The perspective views illustrated in FIG. 3B, 3C are different perspective views on the wide band gap semiconductor device 100 of FIG. 3A.

Referring to FIG. 3A, the source regions 116 (and likewise the channel regions arranged below the source regions 116) are spaced from one another along the second lateral direction x2. The diode region 122 is arranged between neighboring source regions 116 and adjoins to a third part 10823 of the gate dielectric 1082. For example, a main dielectric component of the first part 10821 of the gate dielectric 1082 may be an oxide of silicon, and the main dielectric component of the third part 10823 of the gate dielectric 1082 may be a high-k dielectric material similar to the second part 10822 of the gate dielectric 1082. Depending on process technology, the third part 10822 of the gate dielectric 1082 may include the oxide of silicon. In some other examples, a main dielectric component of the first part 10821 of the gate dielectric 1082 may be equal to a main dielectric component of the second part 10822 of the gate dielectric 1082, e.g. be an oxide of silicon, and a main dielectric component of the third part 10823 of the gate dielectric 1082 may be a high-k dielectric material.

As is illustrated in the schematic perspective views of FIGS. 3B, 3C, the third part 10823 of the gate dielectric 1082 merges into the first part 10821 of the gate dielectric 1082 along the second lateral direction x2.

The schematic cross-sectional view of FIG. 4 illustrates another configuration example of a wide band gap semiconductor device 100 including a trench gate interconnection structure 110. In the illustrated cross-sectional view, the interconnection dielectric 1102 of the trench gate interconnection structure 110 adjoins to the diode region 122 as a non-channel part of the wide band gap semiconductor body. The diode region 122 may completely cover the interconnection dielectric 1102 below the first surface 104, for example.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the disclosed subject matter. This application is intended to cover any adaptations or variations of the specific embodiments discussed herein.

Therefore, it is intended that the disclosed subject matter be limited only by the claims and the equivalents thereof.

1. A wide band gap semiconductor device, comprising:
a wide band gap semiconductor body having a first surface and a second surface opposite to the first surface;
a gate electrode structure arranged in an active transistor area, the gate electrode structure comprising a gate electrode and a gate dielectric arranged between the gate electrode and the wide band gap semiconductor body; and
a gate interconnection structure arranged outside of the active transistor area, the gate interconnection structure comprising an interconnection electrode and an interconnection dielectric arranged between the interconnection electrode and the wide band gap semiconductor body, wherein one or more dielectric constants of a dielectric component of at least one of i) a part of the interconnection dielectric, ii) a first part of the gate dielectric, or iii) a second part of the gate dielectric differ from one or more dielectric constants of a dielectric component of at least one of i) the part of the interconnection dielectric, ii) the first part of the gate dielectric, or iii) the second part of the gate dielectric.

2. The wide band gap semiconductor device of claim 1, wherein the gate electrode structure is a trench gate electrode structure, the first part of the gate dielectric adjoins a channel region, and the second part of the gate dielectric adjoins a non-channel region.

3. The wide band gap semiconductor device of claim 2, wherein a dielectric component of the first part of the gate dielectric is an oxide of silicon, and a dielectric component of the second part of the gate dielectric is a high-k dielectric material.

4. The wide band gap semiconductor device of claim 3, wherein the first part of the gate dielectric comprises the high-k dielectric material, or the second part of the gate dielectric comprises the oxide of silicon.

5. The wide band gap semiconductor device of claim 2, wherein a dielectric component of the first part of the gate dielectric is a high-k dielectric material, and a dielectric component of the second part of the gate dielectric is an oxide of silicon.

6. The wide band gap semiconductor device of claim 2, wherein the first part of the gate dielectric is arranged at a first sidewall of the trench gate electrode structure, and the second part of the gate dielectric is arranged at a second sidewall of the trench gate electrode structure, the second sidewall being opposite to the first sidewall along a first lateral direction.

7. The wide band gap semiconductor device of claim 6, wherein the first part of the gate dielectric adjoins a p-doped body region comprising the channel region, and the second part of the gate dielectric adjoins a p-doped diode region being at least part of the non-channel region.

8. The wide band gap semiconductor device of claim 7, wherein the p-doped diode region adjoins a first part of a bottom side of the trench gate electrode structure.

9. The wide band gap semiconductor device of claim 7, wherein the first part of the gate dielectric merges into the second part of the gate dielectric at a bottom side of the trench gate electrode structure.

10. The wide band gap semiconductor device of claim 9, wherein the p-doped diode region adjoins the first part of the gate dielectric and to the second part of the gate dielectric at the bottom side of the trench gate structure.

11. The wide band gap semiconductor device of claim 2, further comprising a third part of the gate dielectric, wherein the third part of the gate dielectric and the second part of the gate dielectric have a same material composition, and the third part of the gate dielectric is arranged at a first sidewall of the trench gate electrode structure.

12. The wide band gap semiconductor device of claim 11, wherein the third part of the gate dielectric merges into the first part of the gate dielectric along a second lateral direction.

13. The wide band gap semiconductor device of claim 1, wherein the gate interconnection structure includes a trench gate interconnection structure.

14. The wide band gap semiconductor device of claim 13, wherein the trench gate interconnection structure merges into the gate electrode structure.

15. The wide band gap semiconductor device of claim 13, wherein the trench gate interconnection structure adjoins one or more non-channel parts of the wide band gap semiconductor body.

16. The wide band gap semiconductor device of claim 1, wherein a dielectric component of the first part of the gate dielectric is an oxide of silicon, and a dielectric component of the part of the interconnection dielectric is a high-k dielectric material.

17. The wide band gap semiconductor device of claim 1, wherein a dielectric component of the first part of the gate dielectric is an oxide of silicon, and a dielectric component of the part of the interconnection dielectric is a low-k dielectric material.

18. The wide band gap semiconductor device of claim 1, wherein the gate electrode structure is a planar gate electrode structure.

19. A wide band gap semiconductor device, comprising:
a wide band gap semiconductor body having a first surface and a second surface opposite to the first surface;
a gate electrode structure arranged in an active transistor area, the gate electrode structure comprising a gate electrode and a gate dielectric arranged between the gate electrode and the wide band gap semiconductor body; and
a gate interconnection structure arranged outside of the active transistor area, the gate interconnection structure comprising an interconnection electrode and an interconnection dielectric arranged between the interconnection electrode and the wide band gap semiconductor body,
wherein the gate electrode structure is a trench gate electrode structure, a first part of the gate dielectric adjoins a channel region, a second part of the gate dielectric adjoins a non-channel region, the first part of the gate dielectric is arranged at a first sidewall of the trench gate electrode structure, the second part of the gate dielectric is arranged at a second sidewall of the trench gate electrode structure, and the second sidewall is opposite to the first sidewall along a first direction, and
wherein at least one of i) a dielectric component of the first part of the gate dielectric is an oxide of silicon, and a dielectric component of the second part of the gate dielectric is a high-k dielectric material, or ii) a dielectric component of the first part of the gate dielectric is a high-k dielectric material, and a dielectric component of the second part of the gate dielectric is an oxide of silicon.

20. A wide band gap semiconductor device, comprising:
a wide band gap semiconductor body;
a gate electrode structure comprising a gate electrode and a gate dielectric arranged between the gate electrode and the wide band gap semiconductor body; and
a gate interconnection structure comprising an interconnection electrode and an interconnection dielectric arranged between the interconnection electrode and the wide band gap semiconductor body, wherein one or more dielectric constants of a dielectric component of at least one of i) a part of the interconnection dielectric, ii) a first part of the gate dielectric, or iii) a second part of the gate dielectric differ from one or more dielectric constants of a dielectric component of at least one of i) the part of the interconnection dielectric, ii) the first part of the gate dielectric, or iii) the second part of the gate dielectric.
